(19) United States
(12) Patent Application Publication
(10) Pub. No.: US 2006/0262842 A1
(43) Pub. Date: Nov. 23, 2006

(54) Method for signal estimation and extraction

(75) Inventor: Debajyoti Pal, Saratoga, CA (US)

Correspondence Address: CARR & FERRELL LLP, 2200 GENG ROAD, PALO ALTO, CA, 94303, US

(73) Assignee: Tallwood Venture Capital

(21) Appl. No.: 11/134,558

(22) Filed: May 20, 2005

(51) Int. Cl. H03H 7/30; H04B 1/10

(52) U.S. Cl. 375/233; 375/350

(57) ABSTRACT

A method separates a source signal from an interfering signal contain in signals received at multiple sensors. The method estimates the source signal using an adaptive filter characterized by a set of filter coefficients, which are updated by maximizing a distance of the estimated source signal from a Gaussian signal having the same variance as the source signal. In one implementation, the adaptive filter is an adaptive linear combiner. The distance of the estimated source signal from the Gaussian signal may be provided by calculating an entropy function. In one implementation, the distance from Gaussian is estimated using an expectation function involving a fourth moment and a second moment of the source signal.

### BACKGROUND OF THE INVENTION

1. Field of the Invention

The present invention relates to a method for signal processing. In particular, the present invention relates to a method for separating signal sources from sources of interference in a noisy environment.

2. Discussion of the Related Art

In many signal processing applications, such as real time voice or speech processing, signal processing aims at providing high fidelity reproduction of desirable signal sources (e.g., voice of a participant of a teleconference) while attenuating noise and interfering signals (e.g., noise from traffic outside the conference room). Even though integrated circuit technology now provides very powerful digital signal processors, sufficient understanding of the signal processing problem has not been achieved to take advantage of the computational power provided by the digital signal processors to create products for these signal processing applications.

### SUMMARY

The present invention provides a method for separating a source signal from an interfering signal using the signals received at multiple sensors. In one embodiment, the method includes estimating the source signal using an adaptive filter characterized by a set of filter coefficients, and updating the set of filter coefficients by maximizing the distance of the estimated source signal from a Gaussian signal having the same variance as the source signal.

The distance of the estimated source signal from the Gaussian signal may be provided by many functions, such as an entropy function. In one embodiment, the distance from the Gaussian signal may be estimated using an expectation function involving a fourth moment and a second moment of the source signal.

According to one embodiment, the adaptive filter includes an adaptive linear combiner. In one embodiment, the relative delay between the source signal and the interfering signal and multipath effects are ignored.

According to one embodiment, one method uses a singular value decomposition on a matrix to identify the number of significant source signals received at the sensors. In that implementation, the matrix is preconditioned to be zero-mean prior to the singular value decomposition, and a factor matrix of the singular value decomposition is transformed to have equal variance rows.

Alternatively, according another embodiment of the present invention, the adaptive filter may include a multi-dimensional linear equalizer.

In another embodiment, the adaptive filter may include a multidimensional decision feedback equalizer.

The methods of the present invention are applicable to many applications, such as real time speech processing using multiple microphones, medical signal processing using multiple electrodes, and wireless communication using multiple antennae. Real time speech processing finds applications in, for example, speaker phone designs, enterprise phone system designs, tele-conferencing/video-conferencing equipment, automobile voice systems, hands- free telephone equipment and cellular phones.

The present invention is better understood upon consideration of the detailed description below and the accompanying drawings.

### BRIEF DESCRIPTION OF THE DRAWINGS

FIG. 1 is model 100 representing a typical problem in a signal processing application, such teleconferencing.

FIG. 2 illustrates model 200, which is model 100 with the additional assumption that the effects of delays and multipaths may be ignored.

FIG. 3 illustrates model 300, which is a system with two microphones y₁ and y₂; model 300 can accommodate a delay between signal sources S and I.

FIG. 4 shows schematically applying one form of the adaptive linear MDE technique in an adaptive multi-dimensional (MD) linear equalizer (ZFE).

FIG. 5 shows schematically applying the adaptive linear MDE technique in an adaptive MD decision feedback equalizer (DFE).

FIG. 6 provides an example of a decision feedback equalizer.

### DETAILED DESCRIPTION OF THE PREFERRED EMBODIMENTS

The present invention provides a method for separating a signal source from sources of noise and interference.

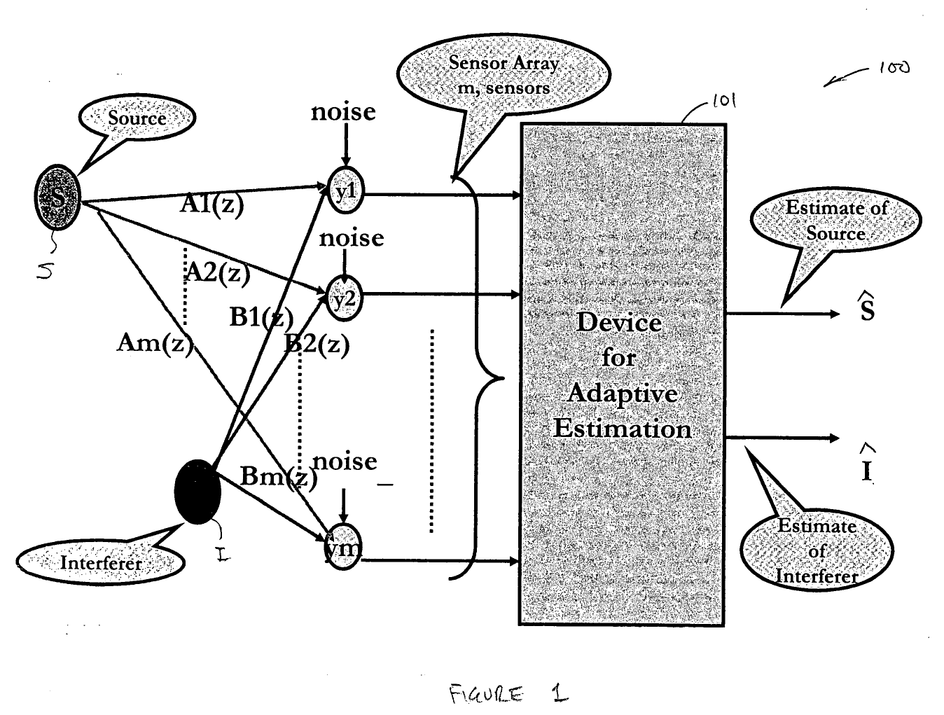

FIG. 1 is model 100 representing a typical problem in a signal processing application. As shown in FIG. 1, model 100 includes desirable signal source S, undesirable interferer I, an array of sensors yₘ (e.g., microphones) and background electrical noise (acoustic noise is included in interferer I). In this model, each sensor yᵢ receives the signals from sources S and I arriving at the sensor as Aᵢ(z) and Bᵢ(z), which include signals arriving directly and indirectly from all signal paths. The indirect signal paths (“multipaths”) result from signal reflections due to the particular acoustical environment. The signals received at the sensors experience different delays because of the different paths. Thus, in FIG. 1, for example, the value of signal I received at sensor y₂ may therefore be represented by the function B₂(z). Similarly, the value of signal S received at sensory y₂ may be represented by the function A₂(z). Further, background electrical noise may be considered random, identically distributed signals at each of sensors y₁, y₂, . . . , yₘ. In this model, a signal processing device 101, which receives the input signals at sensors y₁, y₂, . . . yₘ, provides estimates Ŝ, Î of the source signals S, I.

Model 100 is applicable to many applications, such as real time speech processing using multiple microphones, medical signal processing using multiple electrodes, and wireless communication using multiple antennae. Real time speech processing finds applications in, for example, speaker phone designs, enterprise phone system designs, tele- conferencing/video-conferencing equipment, automobile voice systems, hands-free telephone equipment and cellular phones.

Model 100 can be mapped into a multi-dimensional equalization (MDE) problem. The MDE problem arises in an environment where there are operating multiple transmitters and receivers, and where it is desired to recover each transmitted signal at each receiver. One particular form of the MDE problem, known as the “synchronous MDE problem”, assumes that the sampling clocks at the transmitters and the receivers are synchronized.

Model 100 can also be mapped into a synchronous “far-end cross-talk” (FEXT) cancellation problem, which arises in various high speed networks, such as 1000BASE-T or 10GBASE-T. In a typical environment where model 100 is applicable, such as any of the applications mentioned above, solutions to the FEXT problem are not directly applicable because, unlike the FEXT problem, the transmitters in model 100 are not controlled, and the transmitted signals and the interference signals are not neither identically distributed or Gaussian. Further, whereas in the FEXT problem, pre-determined training or start-up sequence can be provided to assist in speed up convergence in an adaptive solution, such training or start-up sequence is not available in the applications mentioned above. The environment of model 100 can change relative rapidly, so that system parameters of the system must be frequently updated.

One simplification of model 100 is achieved by assuming that the effects of delays and multipaths may be ignored. Assuming further that signal sources S and I are each “m- bit” or 2^{m}-ary sources”¹.
¹ For example, an 8-bit word can be used to represent one of 256 symbols. Thus, an 8-bit source is a 256-ary source. Similarly, a 16-bit source is a 2¹⁶-ary source.

Using this simplification, the signal yₚ at sensor p is given by:
yₚ=aₚS+bₚI+nₚ
in which aₚ, bₚ, nₚ, yₚ are scalers.

This expression may be written in vector form for all sensors:
Y=[AB][SI]¹+N
where
A=[a₁,a₂, . . . ,aₘ]¹, B=└b₁,b₂, . . . bₘ]¹, Y=[y₁,y₂, . . . , yₘ]¹, N=[n₁,n₂, . . . , nₘ]¹
The problem is to provide estimates Ŝ, Î based on the unknown signals and parameters A, B, S, I and N.

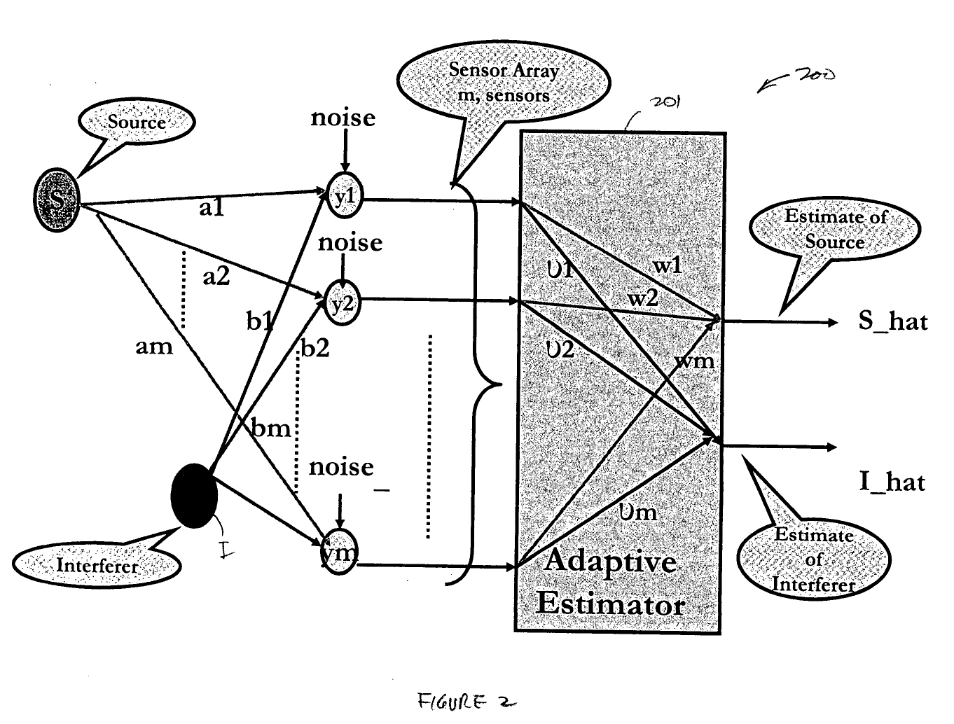

FIG. 2 illustrates this simplified model (i.e., model 200) without delays and multipaths, and one applicable solution known as the “adaptive linear combiner.” The solution has the form:

$$\hat{S} = {\sum }_{m} {w}_{p} {y}_{p} = {W}^{t} Y$$

$$\hat{I} = {\sum }_{m} {v}_{p} {y}_{p} = {V}^{t} Y$$

where wₚ, vₚ are scalar coefficients of signal processing device 201 which may be adaptively updated, W=[w₁,w₂, . . . ,wₘ] and V=[v₁,v₂, . . . ,vₘ] using suitable adaptive filtering techniques.

The update rule of the wₚ, vₚ coefficients of signal processing device 201 can be selected based one or more optimization criteria relevant to the application. The inventor of this application observes that, in the applications relevant to model 200, signals S and I can be assumed to be statistically independent, but their distributions are not necessarily identical or Gaussian. Specifically, the inventor observes that speech or voice signals have a distribution which is significantly non-Gaussian. The interference signal I is frequently an aggregate of multiple and different sources of sound and noise. Thus, relative to the signal distribution of signal S, the signal distribution of signal I is much closer to Gaussian, as can be expected when one considers the central limit theorem. These signal characteristics distinguish model 200 from the assumptions frequently used in digital communication applications, where minimum mean-square error (MMSE) MDE solutions, such as an multi-input, mult-output MMSE solution, can be applied. According to one embodiment of the present invention, one optimization criterion that can be used in an update function of the coefficients in signal processing device 201 is a measure (a “distance function”) of how far the signal characteristic deviate from a Gaussian signal. One such function (“negentropy”) may be defined as:
J(χ)=H(χ_{Gaussian})−H(χ)
where

$$H ( χ ) = - \sum p ( χ )$$

log p(χ) is the entropy function for a random variable χ with a probability density function p(χ), and χ_{Gaussian} is a Gaussian variable having the same variance as variable χ. Thus, negentropy is zero for a Gaussian variable and greater than zero for any other variable having a non-Gaussian distribution. As calculating the entropy function is computationally intensive, a distance function which is less computationally intensive is preferable for real time applications. One such distance function is:
d(χ)=E(χ⁴)−3(E(χ²))² where E is the expectation operator given by

$$E ( χ ) = {\int }_{- ∞}^{∞} g ( χ ) p ( χ ) ⅆ χ$$

This distance function is also zero for a Gaussian variable.

In one embodiment, the update function selects the W vector that maximizes the distance function d(Ŝ) (i.e., choosing the set of wₚ's that make signal Ŝ least resembling a Gaussian signal). In addition, the update function may also select the V vector that minimizes the distance function d(Î) (i.e., choosing the set of vₚ's that make signal Î most closely resembling a Gaussian signal).

One implementation of the above solution for signal processing device 201 with sensors is achieved using software package Matlab, available from The Mathworks, Inc., Natick, Mass. The source code for the implementation is attached herewith as Appendix A.

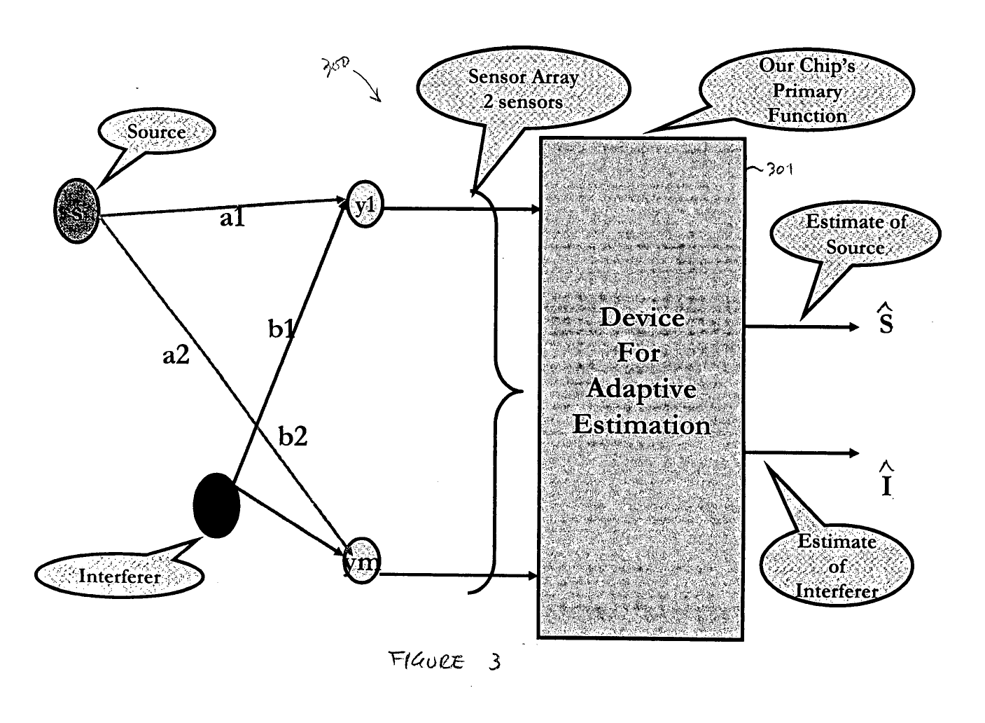

FIG. 3 illustrates model 300, which is a system with two microphones y₁ and y₂. Unlike model 200, model 300 can accommodate an unknown delay τ between signal sources S and I. With the delay included, the the signal yₚ at sensor p at discrete time (i.e., sample time) k is given by:
yₚ[k]=aₚS[k]+bₚI[k−τ]ₚ
in which aₚ, bₚ are scalers and p=1,2.

This expression may be written in vector form for both sensors:
Y=[AB][SI]¹
where A =[a₁, a₂]¹, B=[b₁,b₂]¹, Y=[Y₁, Y₂]¹

Note that, to accommodate the delay τ, at any time, model 300 must take into account past values (i.e., memory) of signals S and I. Thus, the relevant values of input signals S and I are provided in n×1 vectors S and I, where n is a number greater than τ.

To derive the coefficients of adaptive signal processing device 301 and their update rules, one solution takes advantage of a singular value decomposition technique to identify the number of significant signal sources. Singular value decomposition techniques are discussed in the context of stochastic model reduction, for example, in (1) “A Realization Approach to Stochastic Model Reduction and Balanced Stochastic Realizations,” by U. B. Desai and D. Pal, Proc. 21^{st} IEEE Conference on Decision and Control, pp. 1105-1112, 1982; (2) “A Transformation Approach to Stochastic Model Reduction,” by U. B. Desai and D. Pal, IEEE Transaction on Automatic Control, vol. 29, pp. 1097-1100, Dec. 1984; (3) “A Realization Approach to Stochastic Model Reduction,” by U. B. Desai, D. Pal, and R. D. Kirpatrick, International Journal of Control, vol. 42, pp. 821-838, Nov. 1985; and (4) “A New Method of Channel Shortening with Applications to Discrete Multi-Tone (DMT) Systems,” D. Pal, G. Iyengar, and J. M Cioffi, Proc. 1998 IEEE International Conference on Communications, pp. 763-768, May 1998.

In this solution, to simplify calculations, vectors Y₁ and Y₂ of matrix Y[Y₁, Y₂] are each first transformed to zero-mean, i.e., Yⱼ←Yⱼ−E(yⱼ), for j=1,2. Then, a singular value decomposition (SVD) of matrix Y is computed (i.e., Y=UΣV¹), where (1) n×2 matrix U is a matrix formed by unit-norm orthonormal vectors U₁[u₁₁,u₁₂, . . . ,u₁ₙ]¹and U₁[u₁,uⱼ₂, . . . , uⱼₙ]¹, (2) 2×2 matrix Σ is a diagonal matrix of the singular values arranged in non-increasing order, and (3) 2×2 matrix V is a matrix of orthonormal vectors. In the above SVD step, any suitable conventional technique or algorithm for obtaining an SVD of a matrix may be used. (Note that this example discusses the case where there are two (2) sensors. In the general case, where the number of sensors is q, matrix U would be n×q, matrix Σ and matrix V would both be q×q ).

Matrix U is further transformed to obtained matrix

$$Z = {[ {Z}_{1} , {Z}_{2} ]}^{t} = {[ \frac{{U}_{1}}{{σ}_{1}} , \frac{{U}_{2}}{{σ}_{2}} ]}^{t}$$

with
equal variance rows, where

$${σ}_{j} = \sqrt{\frac{{\sum }_{k = 1}^{n} {( {u}_{jk} - {\sum }_{k = 1}^{n} \frac{{u}_{jk}}{n} )}^{2}}{n}} .$$

The adaptive coefficient vectors W=[w₁,w₂]¹ and υ=[υ₁,υ₂]¹ are then defined for the signal processing device 301, which may be referred to as “vector gain” and “complementary vector gain”, respectively. The estimated sources Ŝ and Î are then given by:

Ŝ=Wₒₚₜ^{t}Z and Î=υₒₚₜ^{t}Z, where Wₒₚₜ υₒₚₜ and Σₒₚₜ are the optimal vector gain and optimal complementary vector gain, respectively.

According to one embodiment of the present invention, Wₒₚₜ may be found by maximizing the distance of resulting signal S from a Gaussian signal. In this instance, a vector X=W¹Z=[x₁,x₂, . . . ,xₙ] is defined, and its distance from a Gaussian signal is expressed by d(χ)=E{χ⁴}−3(E{χ²})²=E{χ⁴}−3, where a random variable χ associated with X is calculated. In one embodiment, where E{χ²} is zero, the distance from Gaussian may obtained by calculating

$$d ( χ ) = {\sum }_{k = 1}^{n} \frac{{x}_{k}^{4}}{n} - 3.$$

The maxima Wₒₚₜ can be found using any method, such as a suitable gradient method. Under one gradient method, the gradient of the distance from Gaussian d(χ) with respect to W is calculated (i.e.,

$$\frac{\partial ( d ( χ )}{\partial W} = α E \{ {Z ( {W}^{t} Z )}^{3} \} = αγ ) ,$$

where αis a scalar constant, and γ[γ₁, γ₂]¹ is the value E{Z(W¹Z)³}. The initial value W₀ of vector W may be arbitrarily set, but preferably unit norm and unit variance. W may be iteratively updated until convergence is reached, according to the following steps:
(1) Wₖ₊₁←Wₖ+μγ, wherein μ is a step size.

$${W}_{k + 1} ← \frac{{W}_{k + 1}}{‖ {W}_{k + 1} ‖} \qquad ( 2 )$$

In one embodiment, the components γ₁ and γ₂ of γ are defined as

$${γ}_{j} = {\sum }_{k = 1}^{n} {Z}_{jk} {x}_{k}^{3} .$$

In the general case (i.e., no assumption is made regarding delay or multipaths), the signal γₚ at sensor p is given by: Yp(z) =Ap (z)S(z)+B(z)pI(z)+n , which can be written in vector form for all sensors: Y(z)=[A(z)B(z)][S(z)I(z)l +N(z) where A(z) =[a, (z), a₂ (z), . . . , am (z)I B(z) =[b, (z), b₂(z), . . . , b. (z)l N(z) =[n, (z), n2(z), . . . , nm (Z)

One solution is provided by adaptive linear MDE techniques. Under such a technique, the estimated sources Ŝ and Î are then given by:

$$\begin{matrix}\hat{S} ( z ) = {\sum }_{m} {w}_{p} ( z ) {y}_{p} ( z ) \\ = {W}^{t} ( z ) Y ( z )\end{matrix}$$

$$\begin{matrix}\hat{I} ( z ) = {\sum }_{m} {v}_{p} ( z ) {y}_{p} ( z ) \\ = {V}^{t} ( z ) Y ( z )\end{matrix}$$

where W=[w₁(z),w₂(z), . . . ,wₘ(z)]¹ and V=[v₁(z), v₂(z), . . . , vₘ(z)]¹.

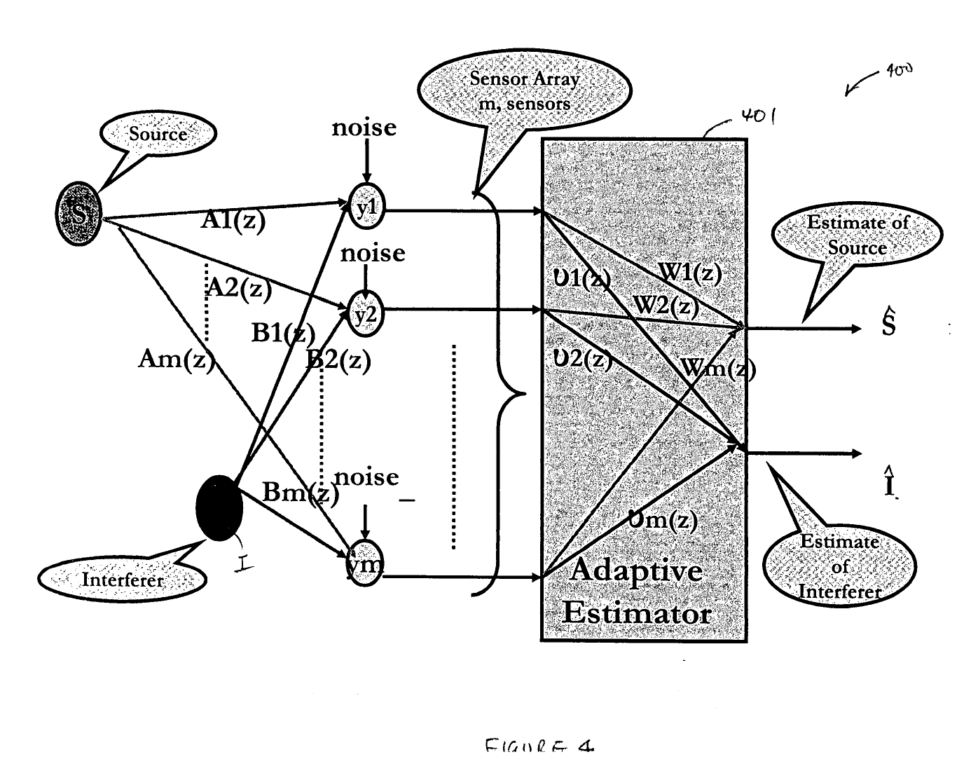

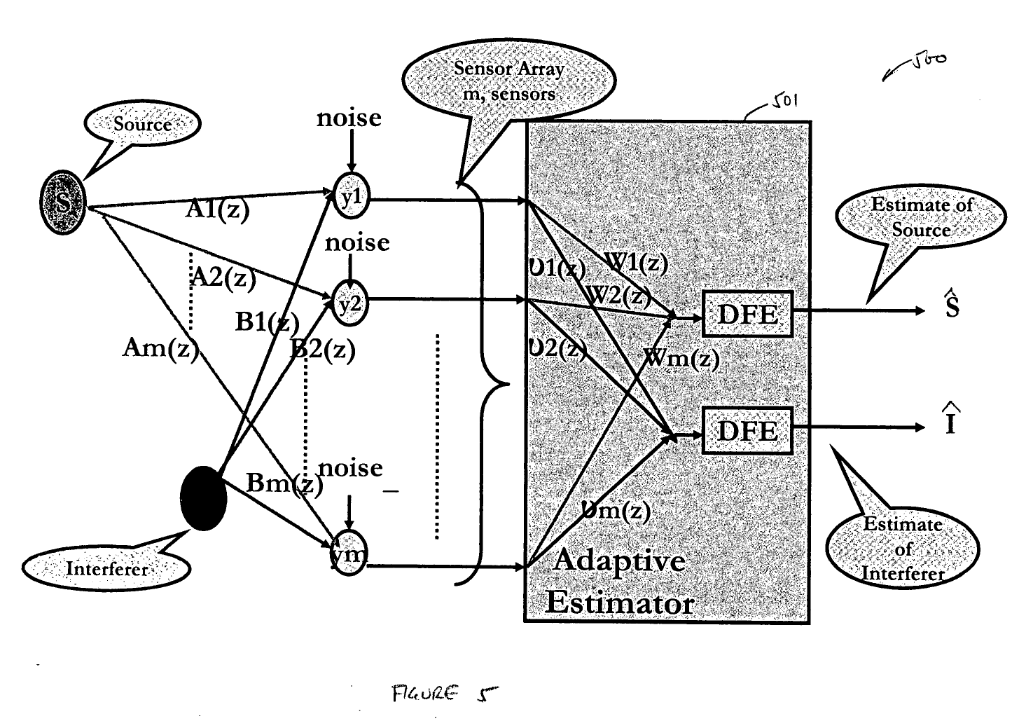

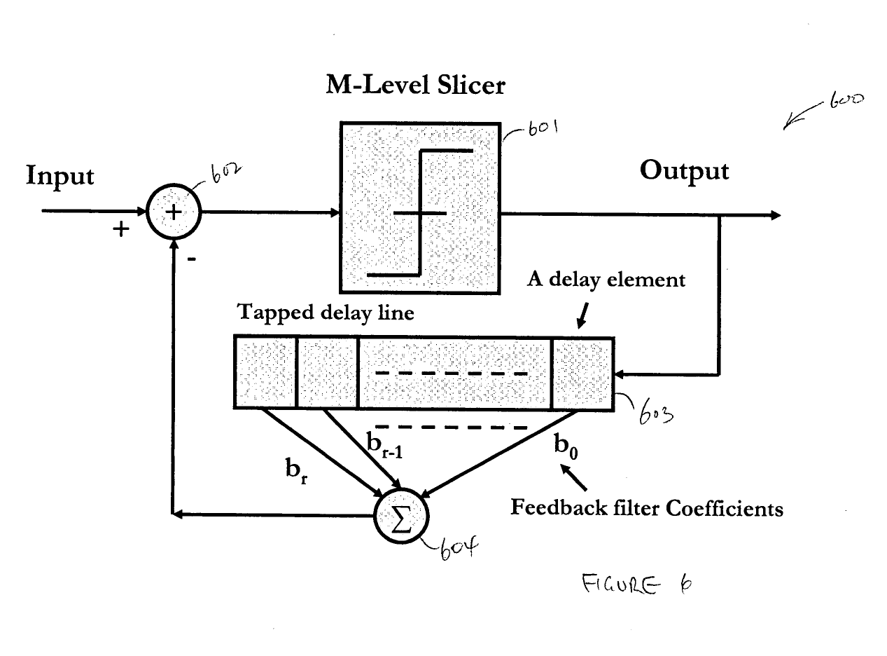

FIG. 4 shows schematically applying one form of an adaptive linear MDE technique in an adaptive multi-dimensional (MD) linear equalizer. Alternatively, the adaptive linear MDE technique may also be applied to an adaptive MD decision feedback equalizer (DFE), such as shown in FIG. 5. An example of a DFE is provided in FIG. 6. In both the MD linear equalizer and MD-DFE solutions, the vector W may be found by optimizing on the distance the estimated source Ŝ (and, optionally, source Î) is away from a Gaussian source.

The above detailed description is provided to illustrate the specific embodiments of the present invention and is not intended to be limiting. Numerous modification and variations within the present invention are possible. The present invention is set forth in the accompanying claims,

APPENDIX A

| | |
|---|---|
| Author: | Debajyoti Pal |
| Organization: | Tallwood Venture Capital |
| Address: | 635 Waverly Street |
| | Palo Alto, CA 94301 |
| | USA |
| Date: | March 25, 2005 |

A sample MATLAB Program
for one source, one interferer and two sensors
Both source and interferer are extracted here.
All rights, including any applicable copyright, reserved by the author
and Tallwood Venture Capital.

listen =1;
M = 2;
N = 4*1e4;
Fs = 10000;
load sensor1_signal; s1 = sensor1_signal(1:N);
load sensor2_signal; s2 = sensor2_signal(1:N);
s1 = s1 - mean(s1); s1 = s1/std(s1);
s2 = s2 - mean(s2); s2 = s2/std(s2);
x = [s1; s2];
if listen soundsc(s1,Fs); end;
pause;
if listen soundsc(s2,Fs); end;
pause;
[U D V] = svd(x′, 0);
z = U;
z = z./repmat(std(z,1), N, 1);
z = z′;
w = randn(1, M)′;
w = w/norm(w);
S_hat = w′ * z;
max_iter = 100;
mu = 4e-2; % Step size.
for iter = 1:max_iter
S_hat= w′ * z;
S_hat3 = S_hat.\hat{ }3;
S_hatS_hat3 = repmat(S_hat3, 2, 1);
gamma = mean( (z.*S_hatS_hat3)′)′;
w = w + mu*gamma;
w = w/norm(w);
end;
if listen soundsc(S_hat, Fs); end;
pause;
v = [0 −1; 1 0]*w;
I_hat = v′*z;
if listen soundsc(I_hat, Fs); end;

I claim:

1. A method for separating a source signal from an interfering signal using the signals received at a plurality of sensors, comprising:
estimating the source signal using an adaptive filter characterized by a set of filter coefficients; and
updating the set of filter coefficients by maximizing the distance of the estimated source signal from a Gaussian signal having the same variance as the source signal.

2. A method as in claim 1, wherein the distance of the estimated source signal from the Gaussian signal is provided by calculating an entropy function.

3. A method as in claim 1, wherein the distance of the estimated source signal from the Gaussian signal is estimated using an expectation function involving a fourth moment of the source signal.

4. A method as in claim 3, wherein the expectation function further involves a second moment of the source signal.

5. A method as in claim 1, wherein the adaptive filter comprises an adaptive linear combiner.

6. A method as in claim 1, wherein the adaptive filter comprises a multi- dimensional linear equalizer.

7. A method as in claim 1, wherein the adaptive filter comprises a mult- dimensional decision feedback equalizer.

8. A method as in claim 1, wherein the adaptive filter presumes that the interfering signal has a predetermined delay relative to the source signal.

9. A method as in claim 1, wherein the updating uses a singular value decomposition technique on a matrix comprising signals received at the plurality of sensors.

10. A method as in claim 9, wherein the matrix is preconditioned to be zero-mean prior to the singular value decomposition.

11. A method as in claim 9, wherein a factor matrix of the singular value decomposition is transformed to have equal variance rows.
